(19) United States
(12) Patent Application Publication
(10) Pub. No.: US 2008/0029484 A1
(43) Pub. Date: Feb. 7, 2008

(54) In-situ process diagnostics of in-film aluminum during plasma deposition

(75) Inventors: Soonam Park, Sunnyvale, CA (US); Farhan Ahmad, Sunnyvale, CA (US); Hemant P. Mungekar, San Jose, CA (US); Young S. Lee, San Jose, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/492,639

(22) Filed: Jul. 25, 2006

(51) Int. Cl. C23F 1/00; G06F 19/00; H01L 21/306; H05H 1/24; C23C 16/00

(52) U.S. Cl. 216/67; 700/121; 118/723 R; 156/345.24; 427/569

(57) ABSTRACT

The concentration of various contaminants in a plasma can be monitored during processing of a substrate such as a silicon wafer, in order to prevent an unacceptable amount of contamination from being deposited on the substrate. The radiation emitted from the plasma through a window in the processing chamber during processing can be detected and measured by a tool such as an optical emission spectrograph (OES) and the relative intensity of peaks in the spectrum corresponding to various contaminants can be analyzed in order to determine contaminant concentration. In one embodiment, the concentration of aluminum in a plasma is monitored during a plasma chemical vapor deposition (CVD) process in order to ensure that the amount of aluminum in the produced device is lower than a maximum threshold amount.

### BACKGROUND OF THE INVENTION

The present invention relates to the deposition of material on a substrate. More particularly, the invention relates to a method and apparatus for monitoring the aluminum content of a plasma when an integrated circuit is manufactured using a plasma processing technique.

One of the steps in the fabrication of modern semiconductor devices is the formation of a thin film on a semiconductor substrate through a chemical reaction of selected gases. One such deposition process is referred to as chemical vapor deposition (“CVD”). Conventional thermal CVD processes supply reactive gases to the surface of a substrate, where heat-induced chemical reactions take place to produce a desired film. Plasma-enhanced CVD techniques, on the other hand, promote excitation and/or dissociation of the reactant gases through the application of radio-frequency (“RF”), microwave, or other energy to a reaction zone near the substrate surface, thereby creating a plasma. The high reactivity of the species in the plasma reduces the energy required for a chemical reaction to take place, and thus lowers the temperature required for such CVD processes as compared to conventional thermal CVD processes. These advantages are further exploited by high-density-plasma (“HDP”) CVD techniques, in which a dense plasma is formed at low vacuum pressures so that the plasma species are even more reactive.

A problem with existing processes for manufacturing devices such as semiconductor chips is that certain contaminants can be deposited onto the surfaces and into films of these devices during manufacture. Since processes such as CVD are used to deposit components of the reactive gases, it is desirable to minimize contaminants in the CVD chamber environment as those contaminants can become deposited in the film and can damage the function of the devices on the substrate wafer, reducing device yields. Metal contaminants such as aluminum can be particularly detrimental to dielectric layers in these devices as the metal contaminants will exhibit electrical properties after thermal processing that can negatively affect gate oxides and other device components and functionality.

A common metal contaminant deposited in such processes is aluminum. A CVD chamber typically contains a variety of components containing aluminum or aluminum compounds, such as an aluminum body, a dome formed of aluminum oxide (e.g., Al₂O₃), and ceramic components formed of aluminum oxide (e.g., Al₂O₃) or aluminum nitride (AlN), any of which can be a source of aluminum particles that can contaminate the substrate surfaces and/or become deposited in a film of the device. A plasma used for deposition can be on the order of about 500° C., with a high level of RF or other energy applied, whereby the number of chemical interactions can result in a substantial number of aluminum components in the plasma during a deposition process. As aluminum is a preferred material for such processing systems, manufacturers typically handle this problem by setting a maximum aluminum content threshold for the devices produced on a wafer or other substrate.

In order to determine the aluminum content of a processed wafer, for example, a wafer generally is taken out of the manufacturing process after a deposition (or etch or other) step and shipped to a lab for analysis in order to determine the aluminum content. The wafer typically is placed in an diagnostic tool such as an Inductively Coupled Plasma Mass Spectrometry (ICP-MS) device to determine the Al contamination in a post-process measurement. The cost to analyze each wafer can be on the order of $500-$1000 in one example, in addition to the cost of the wafer that is wasted for examination. Further, the measurement process can take a substantial amount of time, such as about 3-5 days when shipped to an outside lab, which can result in the production of a number of wafers with unacceptable aluminum content.

It therefore is desirable to develop a way to monitor or determine aluminum content during the manufacturing process in order to reduce waste and lower the cost per chip.

### SUMMARY OF THE INVENTION

Systems and methods in accordance with various embodiments of the present invention provide for in-process determination of contaminant levels. Such determination can be relatively instantaneous, and can be much less expensive than traditional contaminant measurement techniques.

In one embodiment, a substrate processing chamber includes a housing defining the chamber, a substrate holder for supporting a substrate to be processed, and a window for viewing the substrate during processing. A plasma generating system is operatively coupled to the process chamber and configured to generate a plasma in the process chamber in order to process the substrate. Processing of the substrate can include any appropriate processing, such as deposition or etch processing. An analytical tool such as a spectrum analyzer is positioned outside the process chamber and relative to the window, such that the analytical tool can receive radiation emitted by the plasma during processing of the substrate. The analytical tool is operable to measure at least a portion of the radiation emitted, which can correspond to at least one contaminant that might be present in the plasma during processing. In one example, the analytical tool is an optical emission spectrograph (OES) configured to measure the emitted optical radiation as a function of wavelength and generate spectral data in response thereto. A processing device in communication with the analytical tool then can determine a relative concentration of any measured contaminant in the spectrum. In one example, this involves determining an amount of aluminum or an aluminum compound present in the plasma.

A maximum amount threshold can be set for any of the measured contaminants, such that when the determined amount of contaminant concentration in the plasma approaches, is at or near, or exceeds the threshold, processing of substrates in the processing chamber can be stopped. After processing is stopped, the chamber can be cleaned to remove any contamination and can be treated or otherwise processed to reduce the amount of contaminant in the plasma resulting from the process chamber. Treating the process chamber can include any process known in the art, such as seasoning chamber components by applying a layer of material such as silicon oxide on the components to prevent particles such as aluminum particles from passing from the components into the plasma during processing.

These and other embodiments of the present invention, as well as its advantages and features, are described in more detail in conjunction with the text below and attached figures.

### BRIEF DESCRIPTION OF THE DRAWINGS

Various embodiments in accordance with the present invention will be described with reference to the drawings, in which:

FIG. 1 illustrates a portion of a CVD processing chamber of the prior art;

FIG. 2 illustrates a portion of a CVD processing chamber and monitoring system in accordance with one embodiment of the present invention;

FIG. 3 illustrates (a) a spectral analysis of the components of a plasma used for processing and (b) an exemplary correlation between OES measurements and SIMS measurements of contaminant concentration in accordance with one embodiment of the present invention;

FIG. 4 illustrates steps of a method for monitoring aluminum content in a plasma in accordance with one embodiment of the present invention;

FIG. 5 is a simplified diagram of a high-density plasma chemical vapor deposition system that can be used in accordance with one embodiment of the present invention; and

FIG. 6 is a flow chart of an exemplary process control computer program product that can be used to control the exemplary deposition system of FIG. 5 in accordance with one embodiment of the present invention.

### DETAILED DESCRIPTION OF THE EMBODIMENTS

Systems and methods in accordance with various embodiments of the present invention can overcome the aforementioned and other deficiencies in existing processing systems by providing for an in-situ determination of contaminant content. In one embodiment, the optical emission of a plasma in a chemical vapor deposition (CVD) process is examined during a deposition in order to determine the aluminum content of the plasma. A maximum aluminum content threshold can be used to determine when the plasma is at or near a maximum aluminum content, such that processing can be stopped and the CVD system can be treated to reduce the amount of aluminum contaminants passing into the plasma and, accordingly, into or onto the processed devices.

For example, FIG. 1 illustrates a cross-section of a portion of an exemplary plasma deposition chamber 100 useful for depositing a film on a substrate 110, such as a silicon wafer. The substrate is placed on a substrate support 108 in the chamber, which is enclosed by a dome 102 formed of a material such as aluminum. The chamber also includes components such as a gas ring 106 that can include source gas nozzles made from an aluminum oxide ceramic and other aluminum containing components. A gas inlet port 104 allows reactive gases into the chamber, which can be used to form a plasma 112 in the chamber over the substrate 110 as discussed elsewhere herein and known in the art. As discussed above, the heating of the chamber, the application of energy, and the reactions with the plasma gases can cause particles of these components to pass into the plasma, particularly as the chamber ages. These components then can cause contaminants such as aluminum or aluminum fluoride to pass into the plasma 112, resulting in aluminum particles 114 being deposited onto the substrate 110.

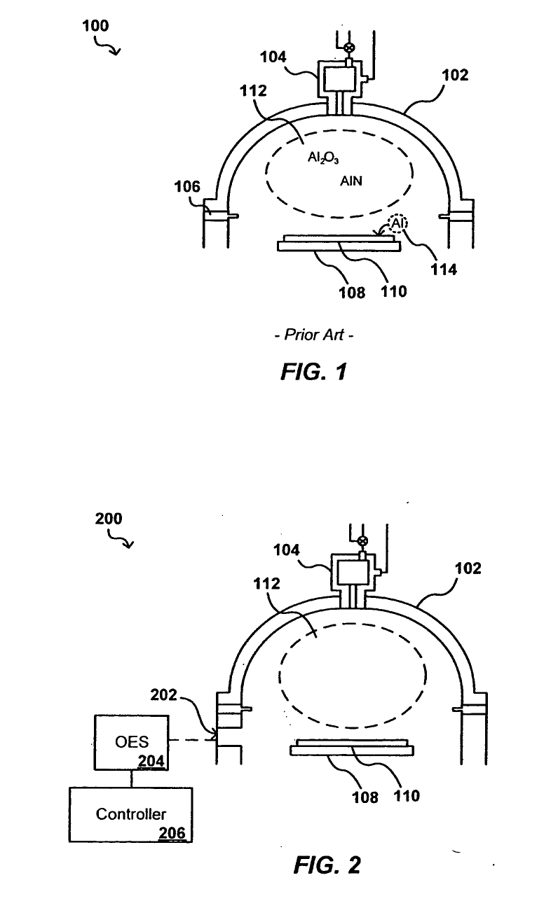

As shown in the example FIG. 2, a processing chamber 200 often includes at least one window 202 allowing an operator or other person or device to see into the chamber 200. Reference numbers are carried over between figures where appropriate for simplicity, but should not be read as a limitation on the various embodiments. A system in accordance with one embodiment takes advantage of such a window by positioning a component analysis tool such as an optical emission spectrograph (OES) relative to the window such that the analysis tool can analyze the components of the plasma. For example, an OES 204 is shown positioned relative to the chamber window 202 such that the OES can capture an optical emission of the plasma 112 during deposition, and a spectral analysis of the emission can be performed to determine aluminum content in the plasma. The generated spectrum and/or spectral analysis can be passed to a controller 206, which can be any appropriate device such as automated controller in a closed loop system or a stand-alone computer or display being monitored by an employee as would be apparent to one of ordinary skill in the art. In one embodiment a residual gas analyzer (RGA) is used to determine concentration, but an RCA typically is installed a distance from the process chamber that makes the concentration measurement lack the desired accuracy for many applications.

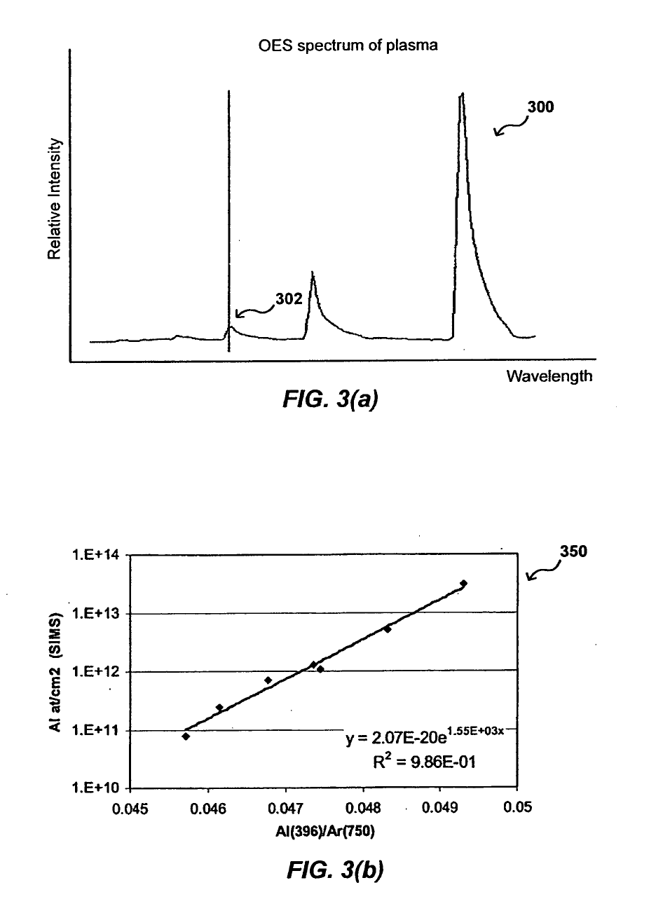

FIG. 3(a) illustrates an exemplary spectrum 300 for a plasma as detected by an OES device or other such spectral analyzer. It should be noted that this spectrum is included for explanation purposes, and should not be interpreted as a limitation on any of the present embodiments. This spectrum is shown as a plot of relative intensity versus wavelength. Since the wavelength of a peak 302 corresponding to aluminum content is known, analyzing such a plot can provide for the determination of relative aluminum content. FIG. 3(b) illustrates an exemplary correlation 350 between OES measurements of the contaminant concentration in the plasma and SIMS measurements indicating the contaminant concentration in the resultant device. A manufacturer therefore can use an approach such as OES with confidence that the process is within an acceptable range of contamination levels. This particular example shows a 98% correlation. If a maximum contaminant concentration is known for a device and the manufacturer of that device has faith in the correlation, then the manufacturer does not need to calibrate the processing tool but can simply rely on the OES data to indicate when contamination levels are getting near an undesirable level.

The maximum relative intensity of the aluminum peak relative to the other components can be known, or can be obtained through an initial calibration procedure, whereby when the relative intensity of the aluminum peak is at or near the maximum threshold value, the chamber being analyzed can be stopped from processing, such as after finishing the present wafer or batch of wafers. The chamber then can be treated to reduce the amount of aluminum passing into the plasma from the deposition tool.

In one calibration procedure for a deposition process, a series of wafers are processed with different aluminum concentrations in the plasma. This can be achieved by injecting reactive gases into the chamber for each test wafer processed. The processed test wafers then can be examined to determine which amount(s) of aluminum in the plasma produce unacceptable amounts of aluminum (and other components) in the device, and/or which produce wafers that do not perform to an acceptable or set standard. After making such a determination, a maximum threshold amount of aluminum can be set (either relative or absolute). The chamber then can be treated as known in the art to remove any residual aluminum content as a result of the calibration. In some systems, a calibration of maximum aluminum content can be used for other deposition tools doing the same processing as well, not simply for the tool used for the calibration.

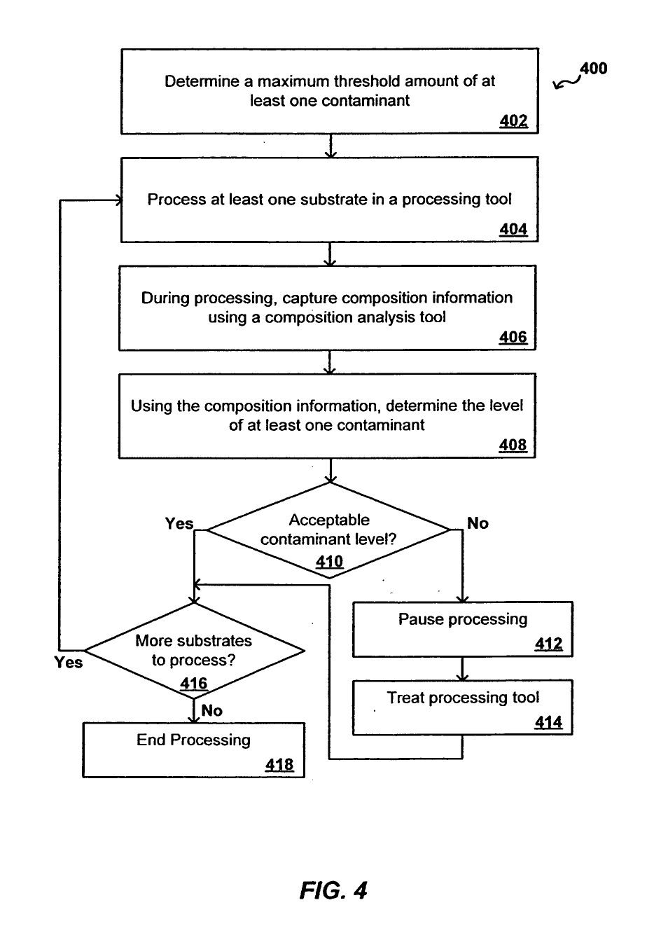

FIG. 4 illustrates steps of an exemplary method 400 for monitoring contamination levels in accordance with one embodiment. In such a method, a maximum threshold amount of a contaminant in a processing tool is determined 402, such as by undertaking a calibration procedure for a process for a chamber to be used for a deposition. This determination can include a single threshold for a single contaminant, or multiple thresholds for multiple contaminants as would be apparent to one of ordinary skill in the art. As discussed above, this can include determining a maximum threshold amount of a metal contaminant such as aluminum and/or an aluminum compound in a plasma. If a calibration procedure is executed, the processing chamber can be treated and/or cleaned to remove any residual contaminants due to the calibration procedure (and any other procedure).

After a maximum contaminant threshold is obtained, the chamber can be used for processing a substrate or other appropriate workpiece 404, such as by depositing films on a silicon wafer using plasma CVD. During the processing of a substrate, the chemical composition of the plasma can be examined using an analytical tool such as an OES 406. The examination can be done at any appropriate time during a series of depositions, such as a regular intervals, irregular intervals, random intervals, every wafer, or at decreasing intervals with age of the processing tool. For example, for new chambers the testing might be done for every 500 wafers, while for older chambers (or where there is a higher Al concentration) the testing could be done for every 100 wafers. For such in-situ measurements, radiation emitted from a window port of the processing chamber as a result of the plasma is captured by a spectral analysis tool such as OES, which can measure the emission from the plasma during a process such as a deposition or etch. After capturing the emission spectrum of the plasma, the level of at least one contaminant, such as aluminum, can be determined from analyzing the emission spectrum 408. For OES, this can involve sending the spectrum or spectrum values to a computer including software for analyzing the spectral values at or near particular wavelengths to determine the concentration of at least one contaminant in the plasma.

If the analysis determines that the contaminant concentration is below a maximum threshold value, or within an acceptable range, or at any other appropriate level or range 410, then another substrate or group of substrates can be processed using the chamber. If the contaminant concentration is at, past, or sufficiently near a maximum concentration threshold, or near the edge of an acceptable range, for example, the processing can be stopped at an appropriate time 412, such as after processing the present substrate or group of substrates. After processing has stopped, the processing tool can be treated to reduce the amount of contaminant 414. In the case of a deposition chamber, for example, the chamber can be cleaned using an appropriate cleaner. This can be any appropriate cleaner, liquid, or material, such as a solvent or de-ionized water. The surfaces of the tool that are exposed to the plasma and/or reactive gases (or other components) then can be seasoned, or coated with a layer of material such as silicon oxide in order to reduce the amount of contamination coming from those surfaces. An appropriate number of test wafers then can be run through the system to remove any contamination due to the cleaning and coating, as known in the art. After the contaminants have been removed, if there are additional wafers to process 416 the processing can begin again. Otherwise, the processing can end and the tool can be used for a different process or purpose 418. It should be noted that the contaminants, peaks, undesirable concentrations, etc., can be different for each process and/or application.

### Exemplary Substrate Processing System

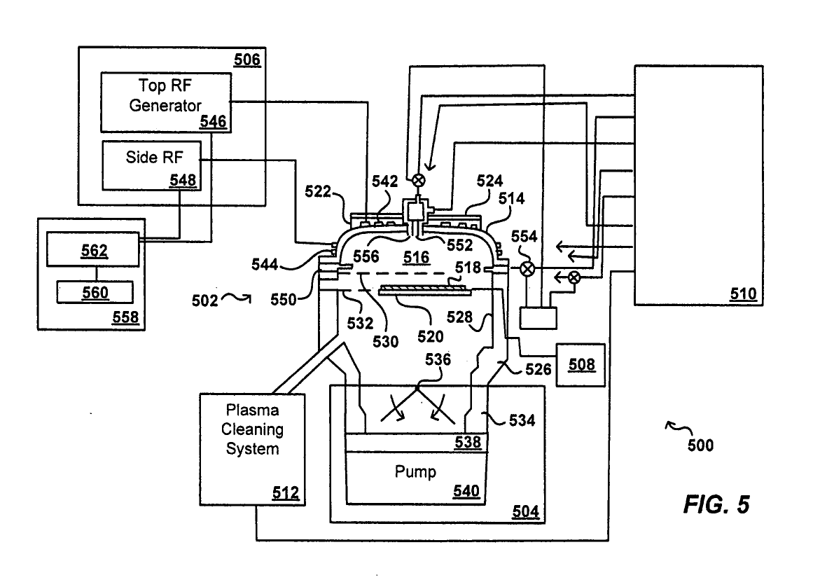

FIG. 5 illustrates an example of a high density plasma chemical vapor deposition (HDP-CVD) system 500 in which a layer can be deposited and a contaminant concentration monitored in accordance with one embodiment. The system 500 includes a chamber 502, a vacuum system 504, a source plasma system 506, a bias plasma system 508, a gas delivery system 510, and a remote plasma cleaning system 512.

The upper portion of the chamber 502 includes a dome 514, which is made of a ceramic dielectric material, such as aluminum oxide or aluminum nitride. The dome 514 defines an upper boundary of a plasma processing region 516. The plasma processing region 516 is bounded on the bottom by the upper surface of a substrate 518 and a substrate support 520.

A heater plate 522 and a cold plate 524 surmount, and are thermally coupled to, the dome 514. The heater plate 522 and cold plate 524 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 502 includes a body 526, which joins the chamber to the vacuum system. A base portion 528 of substrate support 520 is mounted on, and forms a continuous inner surface with, body member 526. Substrates are transferred into and out of the chamber 502 by a robot blade (not shown) through an insertion/removal opening (not shown) in the side of the chamber 502. Lift pins (not shown) are raised and then lowered under the control of a motor (also not shown) to move the substrate from the robot blade at an upper loading position 530 to a lower processing position 532 in which the substrate is placed on a receiving portion of the substrate support 520. The substrate receiving portion can include an electrostatic chuck that secures the substrate to the substrate support 520 during substrate processing. In one embodiment, the substrate support 520 is made from an aluminum oxide or aluminum ceramic material.

The vacuum system 504 includes a throttle body 534, which houses a twin-blade throttle valve 536 and is attached to a gate valve 538 and a turbo-molecular pump 540. It should be noted that the throttle body 534 offers minimum obstruction to gas flow, and allows symmetric pumping. A gate valve 538 can isolate the pump 540 from the throttle body 534, and can also control chamber pressure by restricting the exhaust flow capacity when the throttle valve 536 is fully open. The arrangement of the throttle valve, gate valve, and turbo-molecular pump allow accurate and stable control of chamber pressures from between about 1 milliTorr to about 2 Torr.

The source plasma system 506 includes a top coil 542 and side coil 544, mounted on the dome 514. A symmetrical ground shield (not shown) reduces electrical coupling between the coils. The top coil 542 is powered by top source RF (SRF) generator 546, whereas the side coil 544 is powered by a side SRF generator 548, allowing independent power levels and frequencies of operation for each coil. This dual coil system allows control of the radial ion density in the chamber 502, thereby improving plasma uniformity. The side coil 544 and top coil 542 are typically inductively driven, which does not require a complimentary electrode. In a specific embodiment, the top source RF generator 546 provides up to 2,500 watts of RF power at nominally 2 MHz and the side source RF generator 548 provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 508 includes a bias RF (“BRF”) generator and a bias matching network. The bias plasma system 508 capacitively couples the substrate 518 to the body 526, which act as complimentary electrodes. The bias plasma system 508 serves to enhance the transport of plasma species (e.g., ions) created by the source plasma system 506 to the surface of the substrate. In a specific embodiment, bias RF generator provides up to 5,000 watts of RF power at 13.56 MHz.

The top and side RF generators 546 and 548 include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks match the output impedance of the RF generators 546, 548 with their respective coils 542, 544. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 510 provides gases from several sources into the chamber for processing the substrate via gas delivery lines (only some of which are shown). As would be understood by a person of skill in the art, the actual sources used and the actual connection of delivery lines to the chamber 502 varies depending on the deposition and cleaning processes executed within chamber 502. Gases are introduced into the chamber 502 through a gas ring 550 and/or a top nozzle 552.

In one embodiment, first and second gas sources and first and second gas flow controllers provide gas to a ring plenum in gas ring 550 via gas delivery lines (only some of which are shown). The gas ring 550 has a plurality of source gas nozzles that provide a uniform flow of gas over the substrate. Nozzle length and nozzle angle may be changed to allow tailoring of the uniformity profile and gas utilization efficiency for a particular process within an individual chamber. In one embodiment, the gas ring 550 has twelve source gas nozzles made from an aluminum oxide ceramic.

The gas ring 550 also has a plurality of oxidizer gas nozzles that in one embodiment are co-planar with and shorter than source gas nozzles. In some embodiments it is desirable not to mix source gases and oxidizer gases before injecting the gases into the chamber 502. In other embodiments, oxidizer gas and source gas may be mixed prior to injecting the gases into the chamber 502.

In embodiments where flammable, toxic, or corrosive gases are used, it may be desirable to eliminate gas remaining in the gas delivery lines after a deposition. This may be accomplished using a 3-way valve, such as valve 554, to isolate the chamber 502 from the delivery lines and to vent the delivery lines to a vacuum foreline, for example. Other similar valves may be incorporated on other gas delivery lines. Such 3-way valves may be placed as close to the chamber 502 as practical, to minimize the volume of the un-vented gas delivery line (between the 3-way valve and the chamber). Additionally, two-way (on-off) valves (not shown) may be placed between a mass flow controller (“MFC”) and the chamber or between a gas source and an MFC.

The chamber 502 also has a top nozzle 552 and a top vent 556. The top nozzle 552 and top vent 556 allow independent control of top and side flows of the gases, which improves film uniformity and allows fine adjustment of the film's deposition and doping parameters. The top vent 556 is an annular opening around top nozzle 552. In one embodiment, a first gas source supplies source gas nozzles and the top nozzle. The gases supplied to the top nozzle 552 and top vent 556 may be kept separate prior to flowing the gases into the chamber 502, or the gases may be mixed in a top plenum before they flow into the chamber 502. Separate sources of the same gas may be used to supply various portions of the chamber.

A remote microwave-generated plasma cleaning system 512 is provided to periodically clean deposition residues from chamber components. The cleaning system includes a remote microwave generator that creates a plasma from a cleaning gas source (e.g., molecular fluorine, nitrogen trifluoride, other fluorocarbons or equivalents) in a reactor cavity. The reactive species resulting from this plasma are conveyed to the chamber 502 through a cleaning gas feed port via an applicator tube. The materials used to contain the cleaning plasma (e.g., the cavity and applicator tube) are be resistant to attack by the plasma. The distance between the reactor cavity and feed port should be kept as short as practical, since the concentration of desirable plasma species may decline with distance from the reactor cavity. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as an electrostatic chuck, do not need to be covered with a dummy wafer or otherwise protected, as may be required with an in situ plasma cleaning process.

A system controller 558 controls the operation of the system 500. In one embodiment, the controller 558 includes a memory 560, such as a hard disk drive, a floppy disk drive (not shown), a card rack (not shown), or other kinds of memory, such as ROM, PROM, and others, coupled to a processor 562. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16-bit data bus and 24-bit address bus. The system controller 558 operates under the control of a computer program stored on the hard disk drive or through other computer programs, such as programs stored on a removable disk. The computer program dictates, for example, the timing, mixture of gases, RF power levels and other parameters of a particular process. The interface between a user and the system controller is via a monitor, such as a cathode ray tube (“CRT”) and a light pen.

The system controller 558 operates under the control of a computer program stored in a computer-readable format within the memory 560. The computer program dictates the timing, temperatures, gas flows, RF power levels and other parameters of a particular process. The computer program code can be written in any conventional computer-readable programming language such as 68000 assembly language, C, C++, or Pascal. Suitable program code is entered into a single file, or multiple files, using a conventional text editor and is stored or embodied in a computer-usable medium, such as a memory system of the computer. If the entered code text is in a high level language, the code is compiled, and the resultant compiler code is then linked with an object code of precompiled windows library routines. To execute the linked compiled object code, the system user invokes the object code causing the computer system to load the code in memory. The CPU reads the code from memory and executes the code to perform the tasks identified in the program.

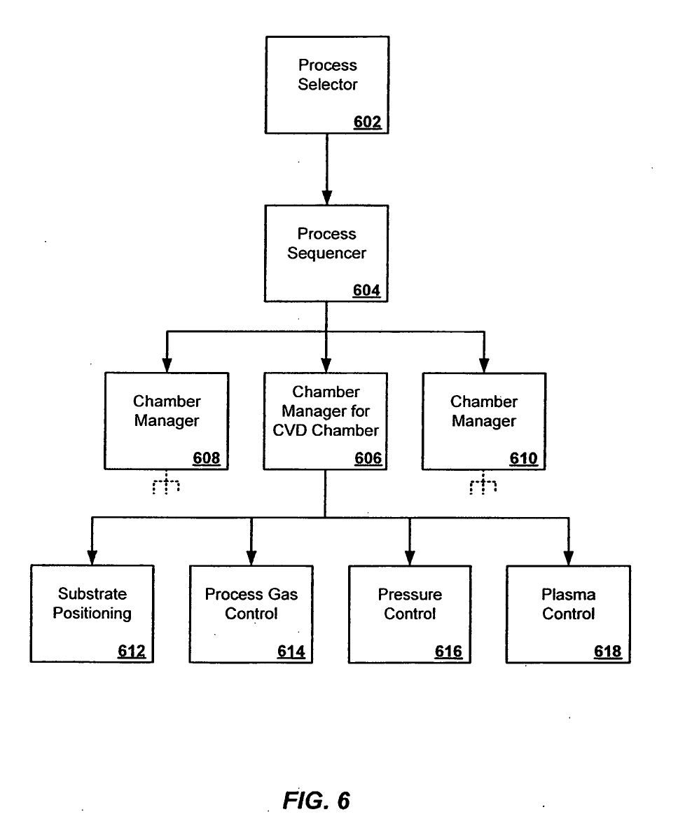

FIG. 6 shows an illustrative block diagram of the hierarchical control structure of computer program 600. A user enters a process set number and process chamber number into a process selector subroutine 602 in response to menus or screens displayed on the CRT monitor by using the light pen interface. The process sets are predetermined sets of process parameters necessary to carry out specified processes, and are identified by predefined set numbers. Process selector subroutine 602 identifies (i) the desired process chamber in a multi-chamber system, and (ii) the desired set of process parameters needed to operate the process chamber for performing the desired process. The process parameters for performing a specific process relate to conditions such as process gas composition and flow rates, temperature, pressure, plasma conditions such as RF power levels, and chamber dome temperature, and are provided to the user in the form of a recipe. The parameters specified by the recipe are entered utilizing the light pen/CRT monitor interface.

The signals for monitoring the process are provided by the analog and digital input boards of the system controller, and the signals for controlling the process are output on the analog and digital output boards of the system controller.

A process sequencer subroutine 604 comprises program code for accepting the identified process chamber and set of process parameters from the process selector subroutine 602 and for controlling operation of the various process chambers. Multiple users can enter process set numbers and process chamber numbers, or a single user can enter multiple process set numbers and process chamber numbers; sequencer subroutine 604 schedules the selected processes in the desired sequence. In one embodiment, sequencer subroutine 604 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, the sequencer subroutine 604 can be designed to take into consideration the “age” of each particular user-entered request, or the present condition of the process chamber being used in comparison with the desired process conditions for a selected process, or any other relevant factor a system programmer desires to include for determining scheduling priorities.

After the sequencer subroutine 604 determines which process chamber and process set combination is going to be executed next, the sequencer subroutine 604 initiates execution of the process set by passing the particular process set parameters to a chamber manager subroutine 606, 608, 610, which controls multiple processing tasks in the chamber and possibly other chambers (not shown) according to the process set sent by sequencer subroutine 604.

Examples of chamber component subroutines are substrate positioning subroutine 612, process gas control subroutine 614, pressure control subroutine 616, and plasma control subroutine 618. Those having ordinary skill in the art will recognize that other chamber control subroutines can be included depending on what processes are selected to be performed in the chamber. In operation, the chamber manager subroutine 606 selectively schedules or calls the process component subroutines in accordance with the particular process set being executed. The chamber manager subroutine 606 schedules process component subroutines in the same manner that the sequencer subroutine 604 schedules the process chamber and process set to execute. Typically, the chamber manager subroutine 606 includes steps of monitoring the various chamber components, determining which components need to be operated based on the process parameters for the process set to be executed, and causing execution of a chamber component subroutine responsive to the monitoring and determining steps.

An exemplary substrate positioning subroutine 612 comprises program code for controlling chamber components that are used to load a substrate onto the substrate support. The substrate positioning subroutine 612 may also control transfer of a substrate into the chamber from, e.g., a plasma-enhanced CVD (“PECVD”) reactor or other reactor in the multi-chamber system, after other processing has been completed.

An exemplary process gas control subroutine 614 has program code for controlling process gas composition and flow rates. The subroutine controls the open/close position of the safety shut-off valves and also ramps up/ramps down the mass flow controllers to obtain the desired gas flow rates. All chamber component subroutines, including the process gas control subroutine 614, are invoked by the chamber manager subroutine 606. The subroutine 614 receives process parameters from the chamber manager subroutine related to the desired gas flow rates.

Typically, the process gas control subroutine 614 opens the gas supply lines, and repeatedly (i) reads the necessary mass flow controllers, (ii) compares the readings to the desired flow rates received from the chamber manager subroutine 606, and (iii) adjusts the flow rates of the gas supply lines as necessary. Furthermore, the process gas control subroutine 614 may include steps for monitoring the gas flow rates for unsafe rates and for activating the safety shut-off valves when an unsafe condition is detected.

In some processes, an inert gas, such as argon, is flowed into the chamber to stabilize the pressure in the chamber before reactive process gases are introduced. For these processes, the process gas control subroutine 614 is programmed to include steps for flowing the inert gas into the chamber for an amount of time necessary to stabilize the pressure in the chamber. The steps described above may then be carried out.

Additionally, when a process gas is to be vaporized from a liquid precursor, for example, tetraethylorthosilane (TEOS), the process gas control subroutine 614 may include steps for bubbling a delivery gas such as helium through the liquid precursor in a bubbler assembly or for introducing the helium to a liquid injection valve. For this type of process, the process gas control subroutine 614 regulates the flow of the delivery gas, the pressure in the bubbler, and the bubbler temperature to obtain the desired process gas flow rates. As discussed above, the desired process gas flow rates are transferred to the process gas control subroutine as process parameters.

Furthermore, the process gas control subroutine 614 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The process gas control subroutine 614 may also control the flow of heat-transfer gas, such as helium (He), through the inner and outer passages in the wafer chuck with an independent helium control (IHC) subroutine (not shown). The gas flow thermally couples the substrate to the chuck. In a typical process, the wafer is heated by the plasma and the chemical reactions that form the layer, and the He cools the substrate through the chuck, which may be water-cooled. This keeps the substrate below a temperature that may damage preexisting features on the substrate.

An exemplary pressure control subroutine 616 includes program code for controlling the pressure in the chamber by regulating the size of the opening of throttle valve in the exhaust portion of the chamber. There are at least two basic methods of controlling the chamber with the throttle valve. The first method relies on characterizing the chamber pressure as it relates to, among other things, the total process gas flow, the size of the process chamber, and the pumping capacity. The first method sets the throttle valve to a fixed position. Setting the throttle valve to a fixed position may eventually result in a steady-state pressure.

Alternatively, the chamber pressure may be measured, with a manometer for example, and the position of the throttle valve may be adjusted according to the pressure control subroutine 616, assuming the control point is within the boundaries set by gas flows and exhaust capacity. The former method may result in quicker chamber pressure changes, as the measurements, comparisons, and calculations associated with the latter method are not invoked. The former method may be desirable where precise control of the chamber pressure is not required, whereas the latter method may be desirable where an accurate, repeatable, and stable pressure is desired, such as during the deposition of a layer.

When the pressure control subroutine 616 is invoked, the desired, or target, pressure control subroutine 616 measures the pressure in the chamber by reading one or more conventional pressure manometers connected to the chamber; compares the measured value(s) to the target pressure; obtains proportional, integral, and differential (PID) values from a stored pressure table corresponding to the target pressure, and adjusts the throttle valve according to the PID values obtained from the pressure table. Alternatively, the pressure control subroutine may open or close the throttle valve to a particular opening size to regulate the pressure in the chamber to a desired pressure or pressure range.

An exemplary plasma control subroutine 618 comprises program code for controlling the frequency and power output setting of the RF generators and for tuning the matching networks. The plasma control subroutine 618, like the previously described chamber component subroutines, is invoked by the chamber manager subroutine.

An example of a system that may incorporate some or all of the subsystems and routines described above would be the ULTIMA™ system, manufactured by APPLIED MATERIALS, INC., of Santa Clara, Calif., configured to practice the present invention. Further details of such a system are disclosed in co-pending, commonly assigned U.S. patent application Ser. No. 08/679,927, filed Jul. 15, 1996, entitled “Symmetric Tunable Inductively-Coupled HDP-CVD Reactor,” having Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha listed as co-inventors, the disclosure of which is incorporated herein by reference. The described system is for explanation purposes only. It would be a matter of routine skill for a person of skill in the art to select an appropriate conventional substrate processing system and computer control system to implement the present invention.

After reading the above description, other recipes that use center-fast deposition will occur to those of ordinary skill in the art. Other variations will also be apparent without departing from the spirit of the invention. These equivalents and alternatives are intended to be included within the scope of the present invention. Therefore, the scope of this invention should not be limited to the embodiments described, but should instead be defined by the following claims.

What is claimed is:

1. A substrate processing system, comprising:
a housing defining a process chamber, the process chamber including a substrate holder for supporting a substrate in the process chamber and a window for viewing the substrate during processing of the substrate in the process chamber;
a plasma generating system operatively coupled to the process chamber and configured to generate a plasma in the process chamber in order to process the substrate; and
an analytical tool positioned outside the process chamber and relative to the window whereby the analytical tool is operable to receive radiation emitted by the plasma during processing of the substrate, the analytical tool being further operable to measure at least a portion of the radiation corresponding to a contaminant in the plasma during processing.

2. A system according to claim 1, wherein:
the analytical tool is operable to measure the relative intensity of an emission spectrum of the plasma as a function of wavelength.

3. A system according to claim 1, wherein:
the analytical tool is an optical emission spectrograph (OES).

4. A system according to claim 1, further comprising:
a processing device operable to receive the measure of at least a portion of the radiation from the analytical tool and determine a relative concentration of the contaminant in the plasma.

5. A system according to claim 1, further comprising:
a gas-delivery system configured to introduce gases into the process chamber; and
a pressure-control system for maintaining a selected pressure within the process chamber during processing.

6. A system according to claim 1, further comprising:
a controller for control the processing of the substrate in the process chamber.

7. A system according to claim 6, wherein processing includes one of depositing a material on, and etching material from, the substrate.

8. A system according to claim 1, wherein the substrate includes a silicon wafer.

9. A system according to claim 1, wherein:
the contaminant is at least one of aluminum and an aluminum-containing compound.

10. A method of processing a substrate, comprising:
placing a substrate in a process chamber;
generating a plasma in a process chamber in order to process the substrate; and
measuring at least a portion of radiation emitted by the plasma during processing of the substrate, the portion corresponding to a contaminant in the plasma during processing.

11. A method according to claim 10, further comprising:
analyzing the measured portion of the radiation to determine a relative concentration of the contaminant in the plasma.

12. A method according to claim 11, wherein:
analyzing the measured portion includes determining a relative intensity of an emission spectrum of the plasma as a function of wavelength.

13. A method according to claim 11, further comprising:
setting a maximum contaminant threshold value for the plasma.

14. A method according to claim 13, further comprising:
determining whether the relative concentration of the contaminant is at or near the maximum contaminant threshold.

15. A method according to claim 13, further comprising:
determining whether to process another substrate in the process chamber based on whether the relative concentration of the contaminant is at or near the maximum contaminant threshold.

16. A method according to claim 15, further comprising:
treating the process chamber to reduce the amount of contaminant in the plasma when the relative concentration of the contaminant is at or near the maximum contaminant threshold.

17. A method according to claim 16, wherein:
treating the process chamber includes seasoning at least a portion of the process chamber with a layer of material.

18. A method according to claim 17, further comprising:
processing a number of test substrates after seasoning the process chamber in order to remove any contamination due to the seasoning.

19. A method according to claim 17, wherein:
the layer of material includes silicon oxide.

20. A method according to claim 11, wherein:
the contaminant is at least one of aluminum and an aluminum-containing compound.

21. A method according to claim 11, further comprising:
flowing a process gas comprising a plurality of precursor gases suitable for forming the plasma into the process chamber.

22. A method according to claim 11, further comprising:
processing the substrate.

23. A method according to claim 22, wherein:
processing the substrate includes one of depositing a material on, and etching material from, the substrate.

24. A computer program product embedded in a computer-readable storage medium, comprising:
computer program code for receiving spectral data corresponding to the optical emission of a plasma during processing of a substrate; and
computer program code for analyzing at least a portion of the spectral data to determine a relative concentration of at least one contaminant in the plasma.

25. A computer program product according to claim 24, further comprising:
computer program code for comparing the relative concentration of at least one contaminant in the plasma to a maximum concentration threshold for each determined contaminant.

26. A computer program product according to claim 24, further comprising:
computer program code for indicating to an operator when the relative concentration of at least one contaminant in the plasma is at or near a maximum concentration threshold for each determined contaminant.
